(19) United States
(12) Patent Application Publication
(10) Pub. No.: US 2011/0088765 A1
(43) Pub. Date: Apr. 21, 2011

(54) Solar Cell Structure

(76) Inventors: Kuang-Chieh Lai, Taipei (TW); Jen-Hung Wang, Taichung (TW); Chun-Hsiung Lu, Hsinchu (TW)

(21) Appl. No.: 12/580,252

(22) Filed: Oct. 16, 2009

(51) Int. Cl. H01L 31/00

(52) U.S. Cl. 136/256

(57) ABSTRACT

A solar cell structure is provided. The solar cell structure includes a substrate, a front transparent conductive oxide (TCO) layer, a primary light absorbing layer, a back TCO layer, and a metal thin film layer stacked from bottom to top. The back TCO layer includes a coarse upper surface. Or alternatively, the solar cell structure includes a substrate, a front TCO layer, at least one first light absorbing layer, at least one interface layer, at least one second light absorbing layer, a back TCO layer, and a metal thin film layer stacked from bottom to top. The interface layer includes a coarse upper surface. Because of the coarse upper surface of the back TCO layer or the interface layer, the light is facilitated for further scattering, so that the light absorbing efficiency can be improved, thus improving the efficiency of the solar cell.

### BACKGROUND OF THE INVENTION

1. Field of the Invention

The present invention relates generally to a solar cell structure, and more particularly, to a solar cell structure having a back transparent conductive oxide (TCO) layer or an interface layer having a coarse upper surface, which is adapted for facilitating to scatter light, thus improving the light absorbing efficiency.

2. The Prior Arts

A typical thin film solar cell usually includes a substrate, a back electrode, a primary light absorbing layer and a front electrode. Conventionally, the front electrode often has a surface configured with humps, and the back electrode is often a high reflective metal back electrode, so as to achieve more light paths in the primary light absorbing layer for capturing the light transmitted therein.

Referring to FIG. 1, there is shown a conventional solar cell structure 1. The solar cell structure 1 includes a substrate 50, a first reflective metal layer 55, a transparent conductive layer 60, a second reflective metal layer 65, a semiconductor thin film layer 70, and a front electrode 75 stacked from the bottom to the top. Each of the first reflective metal layer 55 and the second reflective metal layer 65 has a coarse upper surface. The first reflective metal layer 55, the transparent conductive layer 60, and the second reflective metal layer 65 together constitute a back electrode.

A light L incident to the solar cell 1 can be reflected by the first reflective metal layer 55 and the second reflective metal layer 65 to the semiconductor thin film layer 70. Therefore, the employment of the first reflective metal layer 55 and the second reflective metal layer 65 enhances the photoelectric conversion efficiency of the semiconductor thin film layer 70.

Referring to FIG. 2, it is a schematic diagram illustrating another conventional solar cell structure 2. The solar cell structure 2 includes a back substrate 98, an active body 90, a cermet layer 84, a transparent conductive thin film 82, and a transparent substrate 80 stacked from the bottom to the top. The active body 90 includes a first light absorbing unit 92, a tunnel junction 94, and a second light absorbing unit 96. In the solar cell structure 2, the first light absorbing unit 92 and the second light absorbing unit 96 are stacked in series, and the tunnel junction 94 which is made of a cermet material forms the light path between the first light absorbing unit 92 and the second light absorbing unit 96, thus improving the photoelectric conversion efficiency.

### SUMMARY OF THE INVENTION

A primary objective of the present invention is directed to provide a solar cell structure. The solar cell structure includes a substrate, a front transparent conductive oxide (TCO) layer, a primary light absorbing layer, a back TCO layer, and a metal thin film layer stacked from bottom to top. The back TCO layer includes a coarse upper surface.

Another objective of the present invention is directed to provide a solar cell structure. The solar cell structure includes a substrate, a front TCO layer, at least one first light absorbing layer, at least one interface layer, at least one second light absorbing layer, a back TCO layer, and a metal thin film layer stacked from bottom to top. The interface layer includes a coarse upper surface.

According to the present invention, because the back TCO layer or the interface layer has a coarse upper surface, the light is facilitated for further scattering, so that the light absorbing efficiency can be improved, thus improving the efficiency of the solar cell.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a schematic diagram illustrating a conventional solar cell structure;

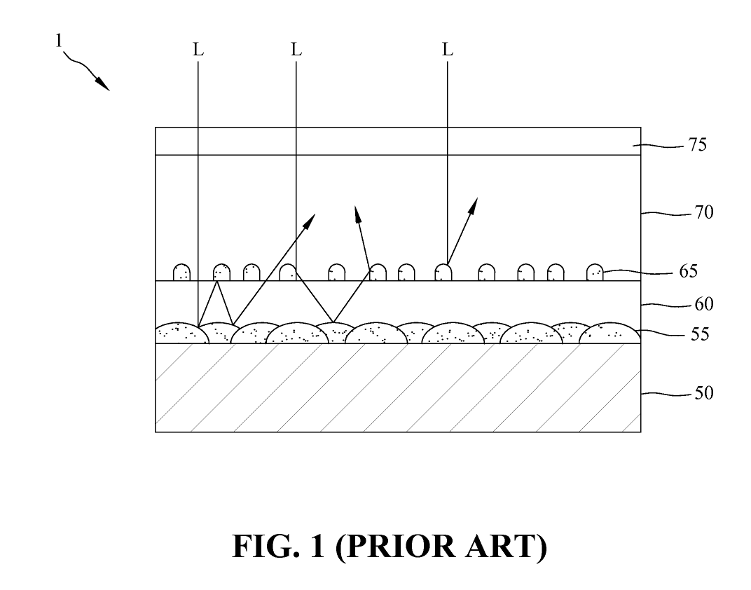

FIG. 2 is a schematic diagram illustrating another conventional solar cell structure;

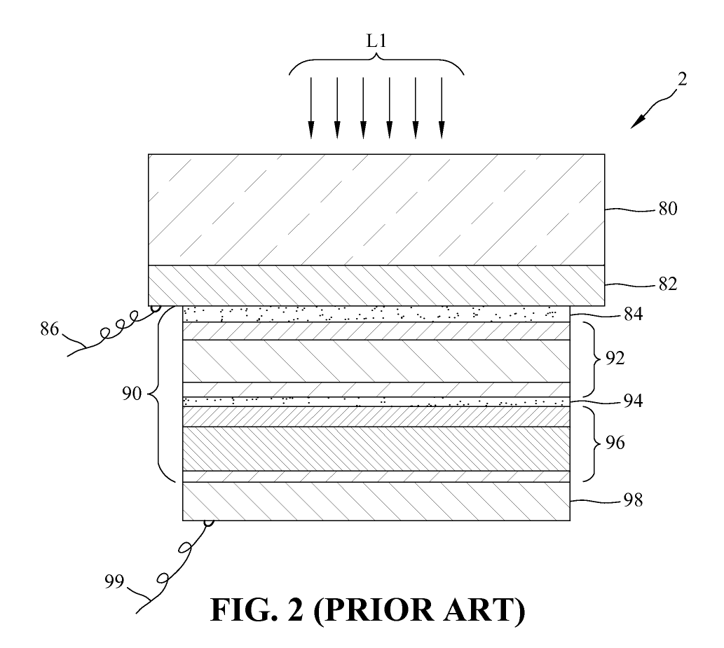

FIG. 3 is a schematic diagram illustrating a solar cell structure according to a first embodiment of the present invention;

FIG. 4 is a schematic diagram illustrating a coarse surface according to the present invention; and

FIG. 5 is a schematic diagram illustrating a solar cell structure according to a second embodiment of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

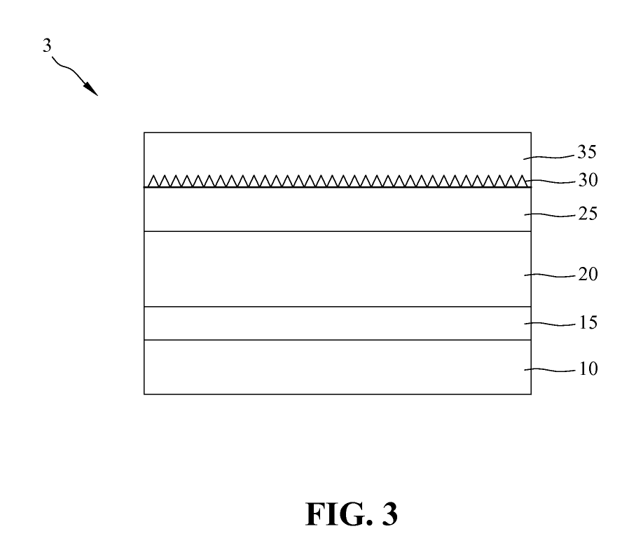

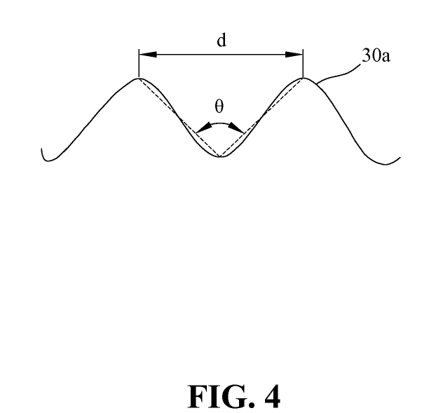

FIG. 3 is a schematic diagram illustrating a solar cell structure according to a first embodiment of the present invention. FIG. 4 is a schematic diagram illustrating a coarse surface according to the present invention. Referring to FIGS. 3 and 4, there is shown a solar cell 3 including a substrate 10, a front transparent conductive oxide (TCO) layer 15, a primary light absorbing layer 20, a back TCO layer 25, and a metal thin film layer 35. The substrate 10, the front TCO layer 15, the primary light absorbing layer 20, and the back TCO layer 25 are sequentially stacked from bottom to top. The back TCO layer 25 includes a coarse upper surface 30. Preferably, the coarse upper surface 30 is formed by a dry etching process. As shown in FIG. 4, the coarse upper surface 30 is configured with a plurality of humps 30a. A distance d is defined between apexes of two adjacent humps 30a. A bottom between the two adjacent humps 30a and the apexes of the two adjacent humps 30a define an included angle θ. Preferably, the distance d is controlled to be less than 200 nm, and the included angle θ is controlled to be within the range of 30° to 150°. The metal thin film layer 35 is stacked on the coarse upper surface 30.

The primary light absorbing layer includes at least one light absorbing layer (not shown in the drawings). The at least one light absorbing layer for example is one of a tandem solar cell, a triple junction solar cell, or a multi junction solar cell.

The front TCO layer 15 and the back TCO layer 25 are preferably made of a ZnO-based material. The substrate 10 is preferably a glass substrate. The dry etching process for example can be a hydrogen plasma processing. The metal thin film layer 35 for example is made of silver (Ag).

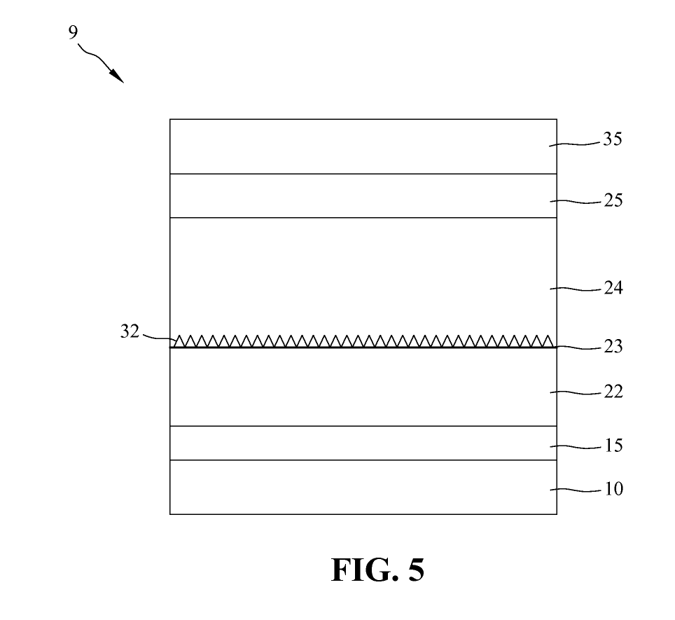

FIG. 5 is a schematic diagram illustrating a solar cell structure according to a second embodiment of the present invention. Referring to FIG. 5, there is shown a solar cell structure 9. The solar cell structure 9 includes a substrate 10, a front TCO 15, at least one first light absorbing layer 22, at least one interface layer 23, at least one second light absorbing layer 24, a back TCO layer 25, and a metal thin film layer 35.

It should be noted that although only one first light absorbing layer, one interface layer, and one second light absorbing layer are exemplified as shown in FIG. 5 for illustration, in the second embodiment each of the first light absorbing layer, the interface layer, and the second light absorbing layer may be a single layer or plural.

The substrate 10, the front TCO layer, the first light absorbing layer 22, and the interface layer 23 are sequentially stacked one on another from bottom to top. The interface layer 23 includes a coarse upper surface 32. Preferably, the coarse upper surface 32 is formed by a dry etching process. The coarse upper surface 32 is configured with a plurality of humps (not shown in the drawings). A distance (not shown in the drawings) is defined between apexes of two adjacent humps. A bottom between the two adjacent humps and the apexes of the two adjacent humps 30a define an included angle (not shown in the drawings). Preferably, the distance is controlled to be less than 200 nm, and the included angle is controlled to be within the range of 30° to 150°. The second light absorbing layer 24, the back TCO layer 25, and the metal thin film layer 35 are then sequentially stacked on the coarse upper surface 32.

The interface layer 23 is preferably made of a ZnO-based material. The substrate 10 is preferably a glass substrate. The dry etching process for example can be a hydrogen plasma processing. The metal thin film layer 35 for example is made of silver (Ag).

The first light absorbing layer 22 and the second light absorbing layer 24 for example can be made of a material selected from the group consisting of I-III-VI compound, amorphous silicon (a-Si), amorphous silicon-germanium (a-SiGe), and microcrystalline silicon (uc-Si). The I-III-VI compound for example includes one of copper-indium-gallium-selenium (CIGS), copper-gallium-selenium (CGS), copper-gallium-selenium (CIS), and silver-indium-gallium-selenium (AIGS).

In summary, according to the present invention, a coarse upper surface is configured on the back TCO layer or the interface layer of the solar cell structure. The coarse upper surface facilitates to further scatter the incident light, so that the light absorbing efficiency of the solar cell can be improved, and so does the efficiency of the solar cell.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A solar cell structure, comprising:
a substrate;
a front transparent conductive oxide (TCO) layer configured on the substrate;
a primary light absorbing layer, configured on the front TCO layer;
a back TCO layer, configured on the primary light absorbing layer, wherein the back TCO layer comprises a coarse upper surface, and the coarse upper surface is configured with a plurality of humps, wherein a distance is defined between apexes of two adjacent humps, and the distance is smaller than 200 nm, and an included angle is defined by a bottom between the two adjacent humps and the apexes of the two adjacent humps, and the included angle is within the range of 30° to 150°; and
a metal thin film layer configured on the coarse upper surface of the back TCO layer.

2. The solar cell according to claim 1, wherein the substrate is a glass substrate.

3. The solar cell according to claim 1, wherein the front TCO layer is made of a ZnO-based material.

4. The solar cell according to claim 1, wherein the back TCO layer is made of a ZnO-based material.

5. The solar cell according to claim 1, wherein the metal thin film layer is made of silver (Ag).

6. The solar cell according to claim 1, wherein the primary light absorbing layer comprises at least one light absorbing layer, and the at least one light absorbing layer is one of a tandem solar cell, a triple junction solar cell, or a multi junction solar cell.

7. A solar cell structure, comprising:
a substrate;
a front transparent conductive oxide (TCO) layer configured on the substrate;
at least a first light absorbing layer, configured on the front TCO layer;
at least one interface layer, configured on the first light absorbing layer, wherein the interface layer comprises a coarse upper surface, and the coarse upper surface is configured with a plurality of humps, wherein a distance is defined between apexes of two adjacent humps, and the distance is smaller than 200 nm, and an included angle is defined by a bottom between the two adjacent humps and the apexes of the two adjacent humps, and the included angle is within the range of 30° to 150°;
at least one second light absorbing layer, configured on the coarse upper surface of the interface layer;
a back TCO layer, configured on the second light absorbing layer; and
a metal thin film layer configured on the back TCO layer.

8. The solar cell according to claim 7, wherein the substrate is a glass substrate.

9. The solar cell according to claim 1, wherein the front TCO layer is made of a ZnO-based material.

10. The solar cell according to claim 1, wherein the back TCO layer is made of a ZnO-based material.

11. The solar cell according to claim 7, wherein the first light absorbing layer is made of a I-III-VI compound, and the I-III-VI compound comprises one of copper-indium-gallium-selenium (CIGS), copper-gallium-selenium (CGS), copper-gallium-selenium (CIS), and silver-indium-gallium-selenium (AIGS).

12. The solar cell according to claim 7, wherein the first light absorbing layer is made of an amorphous silicon (a-Si) material.

13. The solar cell according to claim 7, wherein the back TCO layer is made of a ZnO-based material.

14. The solar cell according to claim 7, wherein the second light absorbing layer is made of a I-III-VI compound, and the I-III-VI compound comprises one of copper-indium-gallium-selenium (CIGS), copper-gallium-selenium (CGS), copper-gallium-selenium (CIS), and silver-indium-gallium-selenium (AIGS).

15. The solar cell according to claim 7, wherein the second light absorbing layer is made of amorphous silicon (a-Si), amorphous silicon-germanium (a-SiGe), microcrystalline silicon (uc-Si).

16. The solar cell according to claim 7, wherein the metal thin film layer is made of silver (Ag).

17. The solar cell according to claim 7, wherein the interface layer is made of a ZnO-based material.
